(19) United States
(12) Patent Application Publication
(10) Pub. No.: US 2011/0180819 A1
(43) Pub. Date: Jul. 28, 2011

(54) LIGHT-EMITTING ARRANGEMENT

(75) Inventors: Rob F. M. Van Elmpt, Roermond (NL); Niels De Koning, Eindhoven (NL); Jean P. Jacobs, Eindhoven (NL)

(73) Assignee: KONINKLIJKE PHILIPS ELECTRONICS N.V., EINDHOVEN (NL)

(21) Appl. No.: 13/063,642

(22) PCT Filed: Sep. 9, 2009
(86) PCT No.: PCT/IB09/53947

§ 371 Date: Mar. 11, 2011

(30) Foreign Application Priority Data
Sep. 16, 2008 (EP) 08164417.1

(51) Int. Cl. H01L 33/64

(52) U.S. Cl. 257/88; 257/E33.075

(57) ABSTRACT

The invention relates to a light-emitting arrangement comprising a printed circuit board, PCB, having at least one electrically and thermally conductive portion, a light-emitting diode, LED, being thermally connected to the at least one electrically and thermally conductive portion by at least one contact of the LED, and a heat release member for dissipating heat generated by the LED, the heat release member being thermally connected to the at least one electrically and thermally conductive portion, wherein the heat generated by the LED is transferred along a heat transfer path extending from the LED via the at least one contact and the at least one electrically and thermally conductive portion to the heat release member.

The light-emitting arrangement according to the invention provides greatly improved heat removal from the LED while using a low-cost glass-epoxy material for the PCB.

### FIELD OF THE INVENTION

The present invention relates to a light-emitting arrangement comprising a light-emitting diode (LED) and a heat release member for dissipating heat generated by the LED.

### BACKGROUND OF THE INVENTION

Light emitting diode (LED) based light-emitting devices are today increasingly used for a wide variety of lighting applications. One problem with LEDs is that they produce heat which must be removed from the device in order to avoid damage of the LED and the device. Overheating may also reduce the performance and/or the efficiency of the LED.

Conventionally, a heatsink placed on the backside (opposite side to the LED) of a printed circuit board (PCB) onto which the LED has been arranged has been used for removing heat, thus requiring the heat to be transported through the PCB. In order to improve the heat transfer, metal core PCBs (MCPCBs) have been used, however having drawbacks as they are expensive. In contrast, glass-epoxy is a low-cost, easily processed material conventionally used for PCBs, however having poor thermal conductivity which provides a major challenge to manufacturers of LED based lighting devices.

U.S. Pat. No. 7,078,728 discloses a surface-mounted LED including a base having heat conductivity, an insulative wiring board fixed to the base and including a conductive pattern and a mounting hole, a light-emitting element chip mounted on a mounting area exposed by the mounting hole, and a reflective frame having heat conductivity and fixed to the base and thermally coupled therewith, to surround the light-emitting element chip, heat generation from the light-emitting element chip being released through both the base and the reflective frame, or either one thereof. However, this arrangement does not provide adequate heat removal from a high-power LED without the use of additional heatsinks attached either to the base or to the reflective frame.

Thus, there is a need in the art for LED arrangements having improved heat removal properties.

### SUMMARY OF THE INVENTION

It is an object of the invention to at least partly overcome the above-mentioned drawbacks of the prior art. In one aspect, the invention relates to a light-emitting arrangement comprising a printed circuit board, PCB, having at least one electrically and thermally conductive portion, a light-emitting diode, LED, for emitting light, the LED being thermally connected to the at least one electrically and thermally conductive portion by at least one contact of the LED, and a heat release member for dissipating heat generated by the LED, the heat release member being thermally connected to the at least one electrically and thermally conductive portion, wherein the heat generated by the LED is transferred along a heat transfer path extending from the LED via the at least one contact and the at least one electrically and thermally conductive portion to the heat release member.

The light-emitting arrangement of the invention provides greatly improved heat removal from the LED, while using of low-cost glass-epoxy materials for the PCB. As a result it is possible to achieve a lower working temperature of the LED and thus better performance, together with reduced production cost. The invention is particularly useful when using high power LED modules.

The arrangement is uncomplicated and also mechanically robust, since the heat release member is attached to the PCB and not to the LED package.

Moreover, since the PCB may have multiple electrically and thermally conductive portions of various shapes and sizes, there is a wide range of alternatives for arranging the heat release member. Thus, the light-emitting arrangement according to the invention allows many different designs.

The contact of the LED may be an electric contact electrically connecting the LED to the at least one electrically and thermally conductive portion. The electric contacts of the LED may thus participate in the transfer of heat from the LED to the heat release member, thus reducing the need for a separate heat transfer member and/or improving the transfer of heat away from the LED.

In embodiments of the invention, the contact is a heat transfer member. Alternatively, the LED may comprise a plurality of contacts including at least one electric contact and at least one heat transfer member. The heat transfer member provides good heat transfer from the LED to the at least one electrically and thermally conductive portion. In particular, the use of a separate heat transfer member in addition to using the electric contacts of the LED for heat transfer may provide improved transfer of heat away from the LED.

The LED and the heat release member may be mounted on one side of the PCB. Additionally, the at least one electrically and thermally conductive portion may be provided on the same side of the PCB. By mounting the heat release member on the front side of the PCB, heat does not have to be transported through or around the PCB. Hence, both low thermal resistance and a less complicated assembly are achieved. Furthermore, the back side of the PCB may be used for purposes other than holding a heat release member, such as for example additional control circuitry. By using the back side of the PCB for mounting control circuitry, the circuitry may be easily protected from damage. Also, separation of heat from the LED and heat from the control circuitry may be achieved.

Furthermore, the control circuitry may at least be partly embedded in a protective material, such as a resin or similar protective material.

In embodiments of the invention, the heat release member is adapted to receive an optical element, for example used for purposes such as collimating and/or redistributing light from the LED. Using the heat release member as a holder for an optical element saves space by evading the need for a separate holder and, by reducing the number of structural elements mounted of the PCB, simplifies the manufacturing process. Furthermore, since the heat release member/optical element holder may be rather large, good heat dissipation may be obtained.

The heat release member may be mounted on the at least one electrically and thermally conductive portion using at least one, or a combination of a solder and conductive glue.

Furthermore, the heat release member may be mounted at a position such that the control circuitry is electromagnetically shielded from the LED. By using the heat release member for electromagnetic shielding, the need for a separate shielding structure is reduced, thus saving space and also simplifying the manufacturing process, which will reduce cost.

Furthermore, in embodiments of the invention, the light-emitting arrangement comprises a plurality of LEDs, each LED being thermally connected to the at least one electrically and thermally conductive portion by at least one contact; and a heat release member for dissipating heat of the plurality of LEDs. Thus, a plurality of LEDs may be used with a single heat release member, hence simplifying the production of systems comprising multiple LEDs and also allowing many different designs of the light-emitting arrangement and/or a lighting system comprising the light-emitting arrangement.

Alternatively, the light-emitting arrangement may comprise a plurality of LEDs, each LED being thermally connected to the at least one electrically and thermally conductive portion by at least one contact, and a plurality of heat release members for dissipating heat generated by the plurality of LEDs, wherein heat of at least one of the plurality of LEDs is transferred along a heat transfer path extending from the at least one of the plurality of LEDs to at least one of the plurality of heat release members. By allowing high variation in the numbers of LEDs and heat release members, and in the ways of connection there between, the light-emitting arrangement according to embodiments of the invention enables many different designs.

### BRIEF DESCRIPTION OF THE DRAWINGS

These and other aspects of the present invention will now be described in more detail, with reference to the appended drawings showing currently preferred embodiments of the invention, in which:

FIG. 1 is a schematic cross-sectional view of a light-emitting arrangement according to a preferred embodiment of the invention;

FIG. 2 is a schematic cross-sectional view of a light-emitting arrangement according to another preferred embodiment of the invention; and

FIG. 3 is a schematic cross-sectional view of a light-emitting arrangement according to still another preferred embodiment of the invention.

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled addressee. Like reference characters refer to like elements throughout.

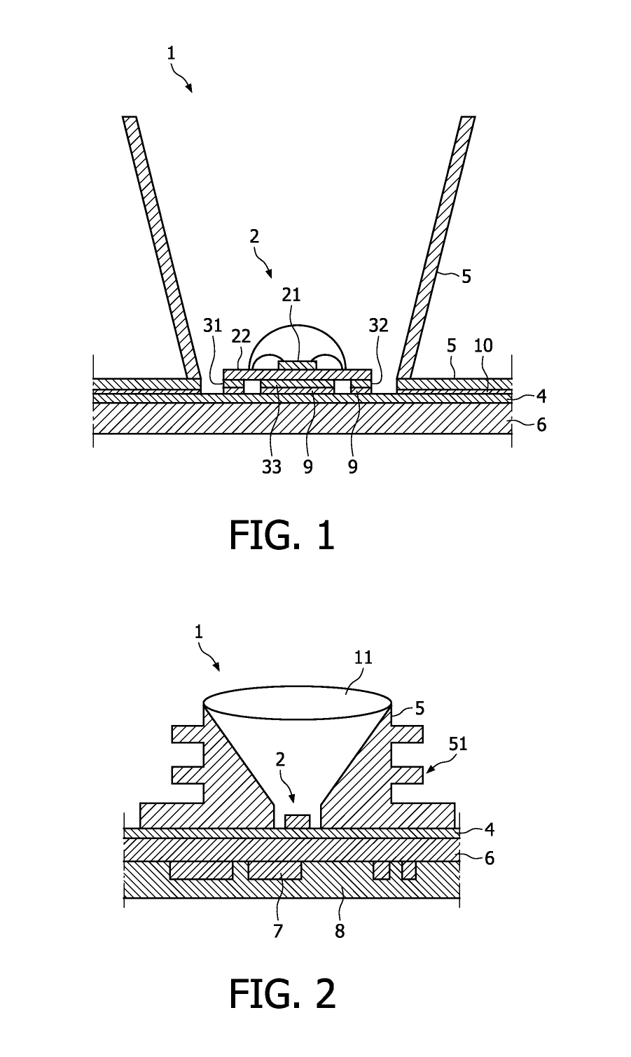

FIG. 1 shows a light-emitting arrangement according to an embodiment of the invention. The light-emitting arrangement 1 comprises a light-emitting diode (LED) 2 mounted on a printed circuit board (PCB) 6. The LED 2 comprises an LED chip 21 arranged on a substrate 22 and electrically and thermally connected to electric contacts 31, 32. The electric contacts 31, 32 are electrically and thermally connected to at least one electrically and thermally conductive portion 4 of the PCB 6.

The PCB 6 may be made of any material conventionally used in the art. The material used for the PCB 6 may have poor thermal conductivity. Typically, the PCB 6 is made of glass-epoxy.

The PCB 6 has at least one electrically and thermally conductive portion 4 formed by electrically and thermally conducting material, such as a metal or a conductive polymer. For example, the at least one electrically and thermally conductive portion 4 may be at least partly made of copper. The at least one electrically and thermally conductive portion 4 is typically a layer covering a part of the PCB 6. The at least one electrically and thermally conductive portion 4 may comprise multiple portions, such as multiple layers each covering a part of the PCB 6. The at least one electrically and thermally conductive portion 4 may have various shapes, and different electrically and thermally conductive portions may have different shapes. Typically, each of the electric contacts 31, 32 is electrically and thermally connected to a separate electrically and thermally conductive portion of the PCB 6.

Furthermore, in the embodiment shown in FIG. 1, the LED 2 is thermally connected to a heat transfer member 33. The heat transfer member 33 is thermally connected to the at least one electrically and thermally conductive portion 4 by means of a solder 9. However, the heat transfer member 33 may also be joined to the at least one electrically and thermally conductive portion 4 by any other conventional thermally conductive joint, such as a thermally conductive glue. The heat transfer member 33 may be electrically insulating. A heat release member 5 is provided for dissipating heat generated during operation of the LED 2. The heat release member 5 is thermally connected to at least one of the at least one electrically and thermally conductive portion 4.

Heat may be transferred from the LED 2 to the electrically and thermally conductive portion 4 and subsequently to the heat release member 5 by various routes. In embodiments of the invention, heat generated by the LED 2 is transferred along a heat transfer path extending from the LED 2 via the electric contacts 31, 32 and the at least one electrically and thermally conductive portion 4 to the heat release member 5. Alternatively, in other embodiments of the invention, the electric contacts 31, 32 are not thermally connected to the heat release member 5. Instead, heat may be transferred along a heat transfer path extending from the LED 2 via the heat transfer member 33 and the at least one electrically and thermally conductive portion 4 to the heat release member 5. In other embodiments of the invention, heat may be transferred from the LED 2 both via the electric contacts 31, 32 and via the heat transfer member 33 to the at least one electrically and thermally conductive portion 4 and subsequently to the heat release member 5.

The electric contacts 31, 32 may be of any conventional material, such as a metal. Other suitable materials for the electric contacts are known to those skilled in the art.

The heat transfer member 33 may be of any conventional thermally conductive material used in the art. Examples of suitable materials for the heat transfer member 33 include metals such as copper and aluminum, thermally conductive polymers, polymers having metal insert, and Thermal Interface Materials (TIM).

The heat release member 5 may be comprised of any material or combination of materials conventionally used for heat sinks, such as metal. Typically, the heat release member is made of a metal, e.g. aluminum, copper, or magnesium, or of a ceramic material.

In the embodiment shown in FIG. 1, heat release member 5 is mounted on the electrically and thermally conductive portion 4 of the PCB 6 by means of solder 10. The heat release member 5 may be mounted on the PBC 6 by any conventional means which provides thermal connection to the electrically and thermally conductive portion 4, such as using a solder or a thermally conductive glue (Thermal interface material). Typically, the heat release member 5 is directly joined to the at least one electrically and thermally conductive portion 4 using a thermally conductive joint, such as solder or thermally conductive glue.

In a further embodiment of the invention illustrated in FIG. 2, the heat release member 5 of the light-emitting arrangement 1 is adapted to receive an optical element 11. The heat release member 5 of FIG. 2 at least partly encloses the LED 2, and defines a space in front of the LED 2 which may be at least partly occupied by one or more optical elements 11. The heat release member 5 may also be arranged to receive a plurality of optical elements of different form, shape and functionality. Examples of optical elements include a lens, a diffuser, a reflector, a collimator and a waveguide.

In order to receive the optical element 11, a side of the heat release member 5 facing the LED 2 may be provided with a shoulder. The one or more optical elements may be mountable for example by gluing, spring-loading or friction fit.

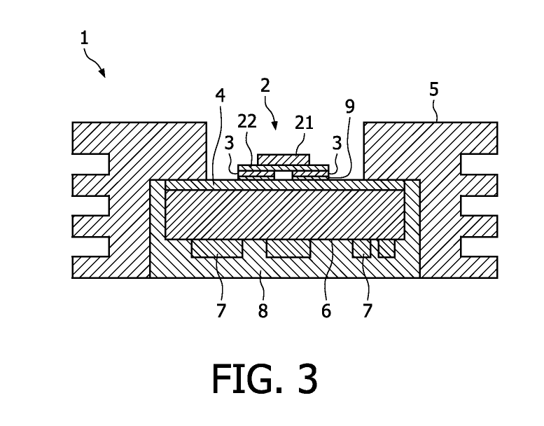

Turning now to FIG. 3 which shows a light-emitting arrangement 1 comprising an LED 2 mounted on a PCB 6 having at least one electrically and thermally conductive portion 4. The LED 2 is thermally connected to the at least one electrically and thermally conductive portion 4 by at least one contact 3. The at least one contact 3 may be an electric contact and/or an electrically insulating heat transfer member. In embodiments of the invention where the contact 3 is an electrically insulating heat transfer member, the LED 2 is electrically connected to the at least one electrically and thermally conductive portion 4 by additional, electric contacts. A heat release member 5 is thermally connected to the at least one electrically and thermally conductive portion 4. The PCB 6 may be as described above.

In the embodiment shown in FIG. 3, the at least one electrically and thermally conductive portion 4, the LED 2 and the heat release member 5 are arranged on the same side of the PCB 6. On the opposite side of the PCB 6, control circuitry 7 is mounted. The control circuitry 7 may comprise, for example, one or more resistors, one or more transistors, one or more integrated circuits, and/or wires or cables. Furthermore, the control circuitry 7 is sealed by a potting 8. The potting 8 protects the control circuitry 7 from damage, such as by moisture.

The heat release member 5 of the embodiment shown in FIG. 3 partly encloses the PCB 6. Thus, the heat release member 5 can be made rather large in order to provide good heat dissipation. Furthermore, the heat release member 5 is provided with cooling flanges 51 to provide good heat release from the heat release member 5.

In other possible embodiments of the invention, the heat release member 5 may be mounted at a position such that the control circuitry 7 is electromagnetically shielded from the LED 2 by the heat release member 5. Electromagnetic shielding of the control circuitry from the LED 2 using the heat release member 5 is particularly useful when the control circuitry 7 and the LED 2 are mounted on the same side of the PCB 6.

The skilled person realizes that the present invention by no means is limited to the preferred embodiments described above. On the contrary, many modifications and variations are possible within the scope of the appended claims. For example, the light emitting arrangement 1 may comprise a plurality of heat release members, so that the LED 2 may be thermally connected to several heat release members. In such embodiments, at least one heat release member may be adapted to receive an optical element.

Additionally, the light-emitting arrangement 1 may comprise a plurality of LEDs. In such embodiments, two or more LEDs may be thermally connected as described above to one and the same heat release member 5. For example, a plurality of LEDs may be mounted on a PCB 6 and thermally connected as described above to a heat release member 5 which also may be mounted on the PCB, so that heat from each LED 2 is transferred via the electrically and thermally conductive portion 4 of the PCB 6 to the heat release member 5. Alternatively, in embodiments of the invention, a plurality of LEDs may be thermally connected as described above to a plurality of heat release members, each LED 2 being thermally connected to at least one heat release member 5 and each heat release member being thermally connected to a least one LED 2. For example, two or more LEDs may be thermally connected to each heat release member 5 of a plurality of heat release members.

Thus, the light-emitting arrangement according to the invention provides greatly improved heat removal from the LED while using low-cost materials for the PCB, such as glass-epoxy. As a result, much improved thermal performance together with reduced production cost may be achieved.

1. Light-emitting arrangement comprising:
a printed circuit board comprising glass-epoxy and having at least one electrically and thermally conductive portion;
a light-emitting diode (LED) for emitting light, said LED being thermally connected to said at least one electrically and thermally conductive portion by at least one contact of said LED; and
a heat release member for dissipating heat generated by said LED, said heat release member being thermally connected to said at least one electrically and thermally conductive portion, said LED and said heat release member being mounted on one side of said printed circuit board;
wherein the heat generated by said LED is transferred along a heat transfer path extending from said LED via said at least one contact and said at least one electrically and thermally conductive portion to said heat release member.

2. Light-emitting arrangement according to claim 1, wherein said contact is an electric contact electrically connecting said LED to said at least one electrically and thermally conductive portion.

3. Light-emitting arrangement according to claim 1, wherein said contact is a heat transfer member.

4. Light-emitting arrangement according to claim 1, wherein said LED comprises a plurality of contacts, including at least one electric contact and at least one heat transfer member.

5. (canceled)

6. Light-emitting arrangement according to claim 1, wherein said at least one electrically and thermally conductive portion is provided on the same side of said PCB.

7. Light-emitting arrangement according to claim 1, further comprising control circuitry, wherein said control circuitry and said LED are mounted on different sides of said printed circuit board.

8. Light-emitting arrangement according to claim 7, wherein said control circuitry is at least partly embedded in a protective material.

9. Light-emitting arrangement according to claim 5, wherein said heat release member is adapted to receive an optical element.

10. Light-emitting arrangement according to claim 1, comprising:
a plurality of LEDs, each LED being thermally connected to said at least one electrically and thermally conductive portion by at least one contact; and
a heat release member for dissipating heat of said plurality of LEDs.

11. Light-emitting arrangement according to claim 1, comprising a plurality of LEDs, each LED being thermally connected to said at least one electrically and thermally conductive portion by at least one contact, and a plurality of heat release members for dissipating heat generated by said plurality of LEDs, wherein heat of at least one of said plurality of LEDs is transferred along a heat transfer path extending from said at least one of said plurality of LEDs to at least one of said plurality of heat release members.

12. Light-emitting arrangement according to claim 1, wherein said heat release member is mounted on said at least one electrically and thermally conductive portion using at least one of solder and glue.

13. Light-emitting arrangement according to claim 1, wherein said heat release member is mounted at a position such that said control circuitry is electromagnetically shielded from said LED.
